(19) United States
(12) Patent Application Publication
(10) Pub. No.: US 2015/0371997 A1
(43) Pub. Date: Dec. 24, 2015

(54) NON-VOLATILE MEMORY DEVICE

(71) Applicant: Kabushiki Kaisha Toshiba, Minato-ku (JP)

(72) Inventors: Masaaki HIGUCHI, Yokkaichi (JP); Katsuyuki SEKINE, Yokkaichi (JP); Fumiki AlSO, Kuwana (JP); Tatsuya OKAMOTO, Inabe (JP); Masaru KITO, Kuwana (JP)

(73) Assignee: Kabushiki Kaisha Toshiba, Minato-ku (JP)

(21) Appl. No.: 14/483,697

(22) Filed: Sep. 11, 2014

Related U.S. Application Data
(60) Provisional application No. 62/016,279, filed on Jun. 24, 2014.

(51) Int. Cl. H01L 27/115; H01L 29/66; H01L 29/423; H01L 21/02; H01L 29/51; H01L 21/28; H01L 21/311; H01L 29/788; H01L 29/49

(52) U.S. Cl. CPC H01L 27/11556; H01L 29/788; H01L 29/66825; H01L 29/42324; H01L 29/4966; H01L 29/513; H01L 21/28273; H01L 21/31111; H01L 21/02365

(57) ABSTRACT

According to one embodiment, a non-volatile memory device includes electrodes, one semiconductor layer, conductive layers, and first and second insulating films. The electrodes are arranged side by side in a first direction. The semiconductor layer extends into the electrodes in the first direction. The conductive layers are provided between each electrode and the semiconductor layer and separated from each other in the first direction. The first insulating film extends between the conductive layers and the semiconductor layer in the first direction. The second insulating film is provided between each electrode and the conductive layers. The conductive layers become smaller in a thickness as the conductive layers are closer to an end in the first direction or a direction opposite to the first direction.

### CROSS-REFERENCE TO RELATED APPLICATIONS

This application is based upon and claims the benefit of priority from U.S. Provisional Patent Application 62/016,279, filed on Jun. 24, 2014; the entire contents of which are incorporated herein by reference.

### FIELD

Embodiments described herein relate generally to a non-volatile memory device.

### BACKGROUND

In order to realize a next-generation non-volatile memory device, the development of a memory cell array having a three-dimensional structure has been progressing. The memory cell array having a three-dimensional structure includes a plurality of word lines stacked and memory cells formed inside a memory hole passing through the word lines. In such a non-volatile memory device, an improvement in the retention characteristics of data is required.

### BRIEF DESCRIPTION OF THE DRAWINGS

FIG. 1 is a schematic cross-sectional view illustrating a non-volatile memory device according to a first embodiment;

FIGS. 2A and 2B are other schematic views illustrating the non-volatile memory device according to the first embodiment;

FIGS. 3A to 5B are energy band diagrams of the memory cell of the non-volatile memory device according to the first embodiment;

FIGS. 6A to 6J are schematic cross-sectional views illustrating a method for manufacturing the non-volatile memory device according to the first embodiment;

FIG. 7 is a schematic diagram illustrating a structure of a memory cell according to a variation of the first embodiment; and

FIGS. 8A to 8C are examples of schematic views showing a non-volatile memory device according to a second embodiment.

### DETAILED DESCRIPTION

According to one embodiment, a non-volatile memory device includes a plurality of electrodes, at least one semiconductor layer, conductive layers, a first insulating film, and a second insulating film. The electrodes are arranged side by side in a first direction. At least one semiconductor layer extends into the electrodes in the first direction. The conductive layers are provided between each of the electrodes and the semiconductor layer. The conductive layers are separated from each other in the first direction. The first insulating film extends between the conductive layer and the semiconductor layer in the first direction along the semiconductor layer. The second insulating film is provided between each of the electrodes and the conductive layers. The conductive layers become smaller in a thickness in a direction perpendicular to the first direction as the conductive layers are closer to an end in the first direction or a direction opposite to the first direction, and have a convex shape in a direction from the semiconductor layer toward each of the electrodes.

Various embodiments will be described hereinafter with reference to the accompanying drawings. The same portions in the drawings are denoted by the same reference numerals and signs, and thus the detailed description thereof will be appropriately omitted, and different portions will be described. Meanwhile, the drawings are schematic or conceptual, a relationship between the thickness and the width of each portion, a size ratio between the components, and the like are not necessarily identical to those in reality. Even when the same portions are shown, mutual dimensions or ratios may be shown differently in the drawings. The arrangement of each element may be described using XYZ-axis directions shown in the drawings. The X-axis, the Y-axis, and the Z-axis are orthogonal to each other, a Z-axis direction may be represented as an upward direction, and a direction opposite thereto may be represented as a downward direction.

### First Embodiment

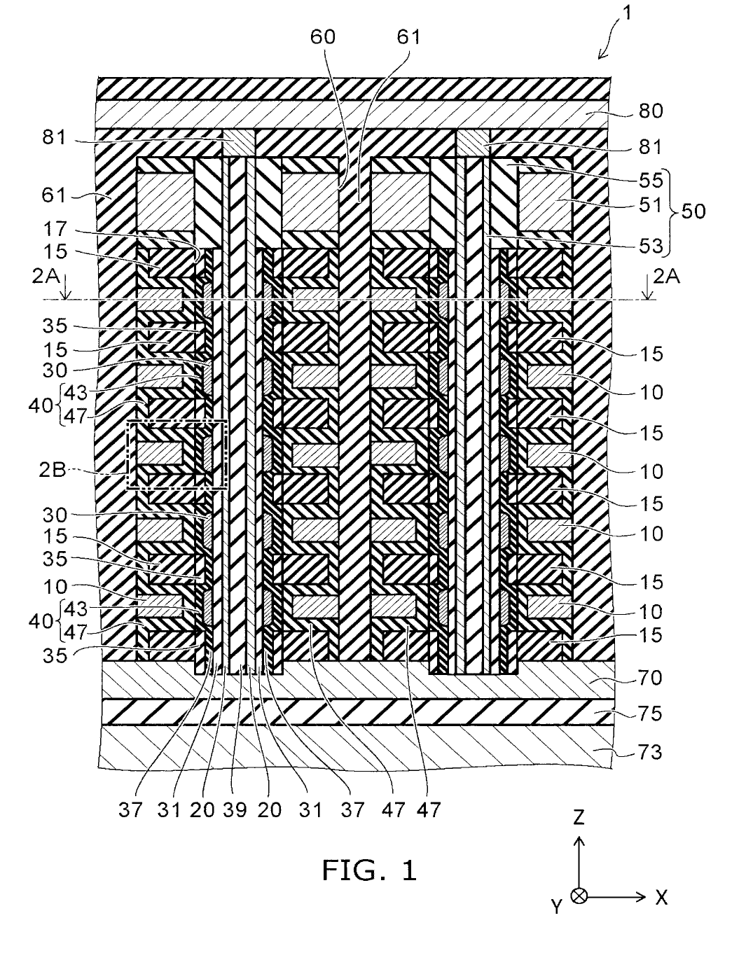

FIG. 1 is a schematic cross-sectional view illustrating a non-volatile memory device 1 according to a first embodiment. The non-volatile memory device 1 shown in FIG. 1 is one example, and the embodiment is not limited thereto.

The non-volatile memory device 1 includes, for example, a plurality of electrodes (hereinafter, control gate 10) arranged side by side in a first direction (hereinafter, Z-direction) perpendicular to a substrate, and at least one semiconductor layer (hereinafter, channel body 20). The channel body 20 extends into a plurality of control gates 10 in the Z-direction.

The control gates 10 are arranged side by side in the Z-direction through, for example, interlayer insulating films 15. The control gates 10 and the interlayer insulating films 15 are alternately arranged in the Z-direction. The channel body 20 is provided inside, for example, a memory hole 17 passing through the control gate 10 and the interlayer insulating film 15 in the Z-direction.

The non-volatile memory device 1 includes a conductive layer 30, a first insulating film 31, and a second insulating film 40 between each of the plurality of control gates 10 and the channel body 20. The conductive layer 30 is provided between each control gate 10 and the first insulating film 31. The conductive layers 30 are provided so as to be separated from each other in the Z-direction.

The first insulating film 31 extends between the channel body 20 and the conductive layer 30 in the Z-direction along the channel body 20. The first insulating film 31 is in contact with, for example, the conductive layer 30. The second insulating film 40 is provided between each control gate 10 and the conductive layer 30.

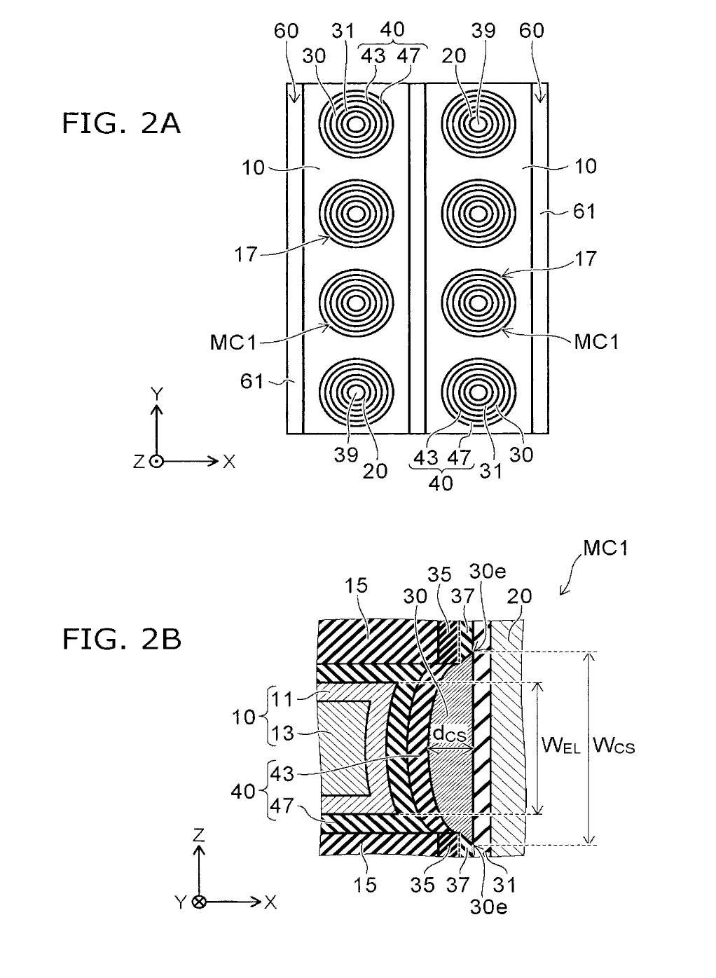

Next, the non-volatile memory device 1 will be described in detail with reference to FIG. 1 to FIG. 2B. FIGS. 2A and 2B are other schematic views illustrating the non-volatile memory device 1 according to the first embodiment. FIG. 2A is a cross-sectional view taken along line 2A-2A shown in FIG. 1. FIG. 2B is a partially enlarged cross-sectional view showing a region 2B shown in FIG. 1, and shows a structure of a memory cell MC1.

As shown in FIG. 1, the plurality of control gates 10 are provided on a source interconnection 70. The source interconnection 70 is provided on, for example, a substrate 73 with an interlayer insulating film 75 interposed therebetween. The memory hole 17 is in communication with the source interconnection 70. The channel body 20 extends in the Z-direction along the inner wall of the memory hole 17. The channel body 20 is electrically connected to the source interconnection 70 at the bottom of the memory hole 17.

A selection transistor 50 is provided on the uppermost layer of the plurality of control gates 10 in the Z-direction. The selection transistor 50 includes a selection gate 51, a channel body 53, and a gate insulating film 55. The channel body 53 is electrically connected to the channel body 20. The gate insulating film 55 is provided between the selection gate 51 and the channel body 53.

Further, a bit line 80 is provided on the selection transistor 50. The bit line 80 is electrically connected to the channel body 53 through a contact plug 81. The bit line 80 is electrically connected to the channel body 20 through the selection transistor 50.

The bit line 80 extends, for example, in the X-direction. The bit line 80 is electrically connected to a plurality of channel bodies 20 arranged side by side in the X-direction. The selection transistor 50 selects one of the plurality of channel bodies 20 which are electrically connected to one bit line 80. That is, the selection transistor 50 provided on one channel body 20 is set to be in an on state, and the selection transistor 50 provided on another channel body 20 is set to be in an off state, to thereby select one channel body 20.

As shown in FIG. 2A, the control gate 10 extends in the Y-direction. The plurality of control gates 10 are arranged side by side in the X-direction. An insulating film 61 is provided between the control gates 10 next to each other. The insulating film 61 is provided inside a slit 60 which is provided between the control gates 10 next to each other.

The slit 60 is, for example, a groove having a depth from the selection gate 51 to the source interconnection 70, and extends in the Y-direction. In this example, the slit 60 is formed for each memory hole 17 in the X-direction, but the embodiment is not limited thereto. For example, the slit 60 may be formed in for each of a plurality of memory holes arranged side by side in the X-direction. In other words, the control gate 10 may be formed so as to surround two or more memory holes which are respectively arranged side by side in the X-direction and the Y-direction.

As shown in FIG. 2A, one control gate 10 is provided with the plurality of memory holes 17. In this example, the plurality of memory holes 17 are formed so as to be lined up in a row in the Y-direction, but the embodiment is not limited to this example. The plurality of memory holes passing through one control gate 10 may be arranged, for example, in a matrix within the X-Y plane, and may be arranged in zigzag.

The cross-section of the memory hole 17 perpendicular to the Z-direction is, for example, circular. The memory hole 17 includes an insulating core 39, the channel body 20, the first insulating film 31, the conductive layer 30, and the second insulating film 40 in this order, from the center thereof. The second insulating film 40 includes a first layer 43 and a second layer 47.

The memory cell MC1 is formed between each control gate 10 and the channel body 20. The memory cell MC1 includes the first insulating film 31, the conductive layer 30, and the second insulating film 40 from the channel body 20 side. The first insulating film 31 functions as, for example, a tunnel insulating film. The conductive layer 30 serves as a charge storage layer (or, floating gate), for example. The second insulating film 40 functions as, for example, a block insulating film.

As shown in FIG. 2B, the second insulating film 40 is provided between the control gate 10 and the conductive layer 30. The first layer 43 is located between the conductive layer 30 and the second layer 47. The second layer 47 is located between the control gate 10 and the first layer 43. The second layer 47 also extends between the control gate 10 and the interlayer insulating film 15 adjacent thereto. The dielectric constant of the second layer 47 is higher than the dielectric constant of the first layer 43.

The control gate 10 includes, for example, a first electrode layer (hereinafter, electrode layer 11) and a second electrode layer (hereinafter, electrode layer 13). The electrode layer 11 is, for example, a barrier metal layer, and prevents metal atoms contained in the electrode layer 13 from being diffused into the memory cell MC1.

The non-volatile memory device 1 further includes a third insulating film 35 and a fourth insulating film 37. The third insulating film 35 is located between the interlayer insulating film 15 and the fourth insulating film 37. The fourth insulating film 37 is provided between the first insulating film 31 and the third insulating film 35. As described later, the fourth insulating film 37 is, for example, an oxidized portion of a conductive film 130 serving as the conductive layer 30.

As shown in FIG. 2B, the conductive layer 30 becomes smaller in a thickness d_{CS} in a direction perpendicular to the Z-direction as the conductive layer is closer to an end 30e in the Z-direction or a direction opposite thereto. In addition, the conductive layer 30 has a convex shape in a direction (for example, −X-direction) from the channel body 20 toward the control gate 10. Further, a width W_{EL} of the control gate 10 in the Z-direction is smaller than a width W_{CS} of the conductive layer 30 in the Z-direction.

The memory cell MC1 includes the conductive layer 30 provided in a convex shape toward the control gate 10. For this reason, for example, the control gate 10 becomes larger in area that is in contact with the block insulating film (second insulating film 40), as compared to a case where the memory cell includes a flat charge storage layer. Thereby, it is possible to increase capacitive coupling between the control gate 10 and the memory cell MC1, so-called coupling. In addition, in the conductive layer 30, it is also possible to store charge in a portion extending in the Z-direction further than the control gate 10. For this reason, in the memory cell MC1, it is possible to increase the amount of charge capable of being stored.

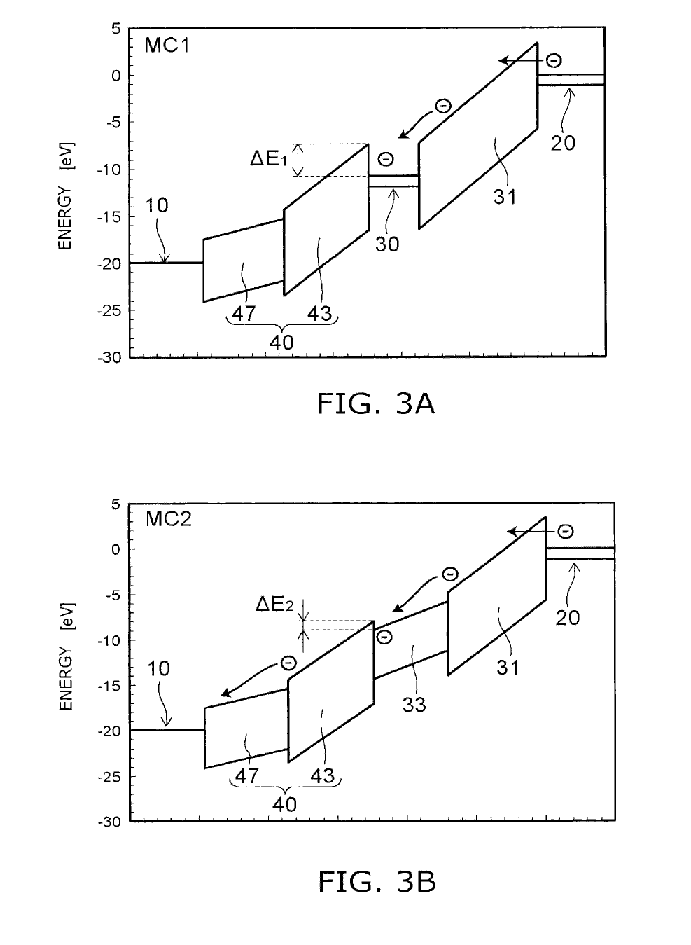

Next, operations of the non-volatile memory device 1 according to the first embodiment will be described with reference to FIGS. 3A to 5B. FIGS. 3A to 5B are energy band diagrams illustrating the memory cell. FIGS. 3A, 4A and 5A are band diagrams of the memory cell MC1 of the non-volatile memory device 1 according to the embodiment. FIGS. 3B, 4B and 5B are band diagrams of a memory cell MC2 of a non-volatile memory device according to a comparative example. In each drawing, the control gate 10 is a metal, and the channel body 20 and the conductive layer 30 are semiconductors, for example, silicon.

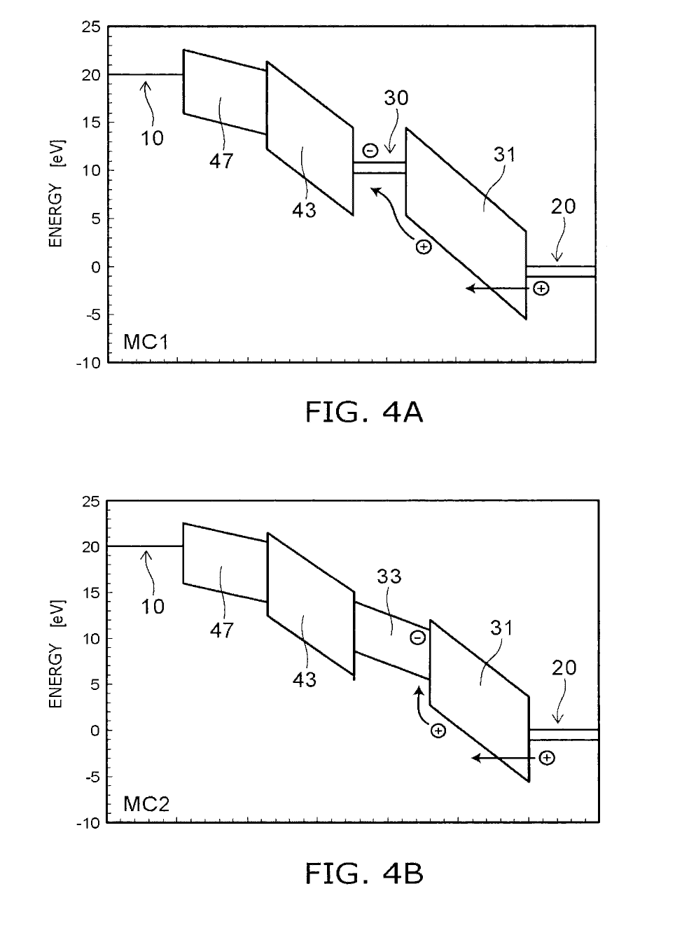

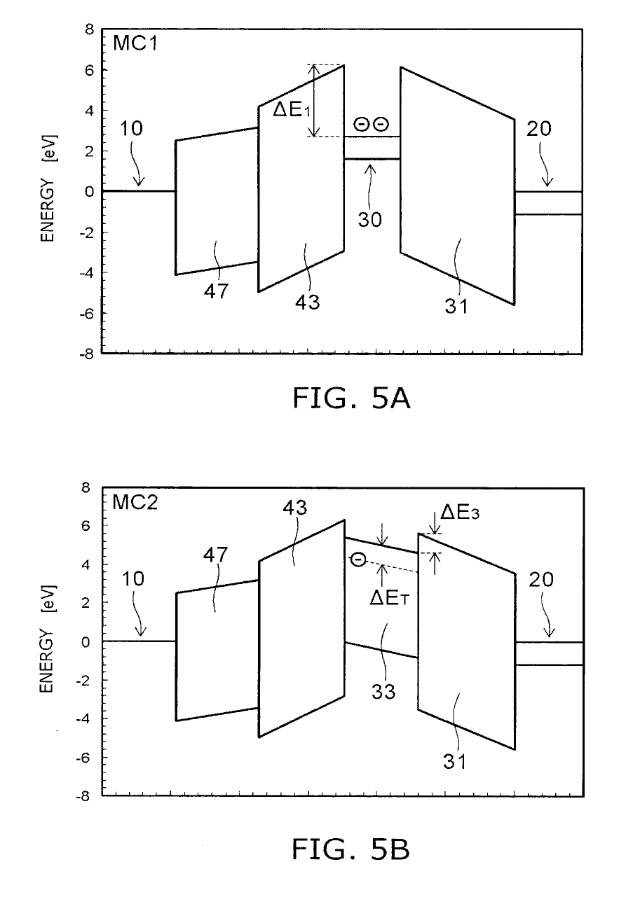

FIGS. 3A and 3B show data writing operations. FIGS. 4A and 4B show states in which data is held. FIGS. 5A and 5B show erasing operations of data.

As shown in FIGS. 3A and 3B, during data writing, a potential difference of, for example, 20 V is given between the control gate 10 and the channel body 20. Thereby, an electric field occurs in the first insulating film 31, and electrons of the channel body 20 pass through the first insulating film 31 and are injected into the conductive layer 30.

In the example of FIG. 3A, an energy barrier ΔE₁ is present between the conductive layer 30 and the second insulating film 40, and thus the transfer of the electrons from the conductive layer 30 to the second insulating film 40 is interfered with. Thereby, it is possible to store electrons in the conductive layer 30, and to store data. In addition, it is possible to suppress a gate leakage current flowing from the conductive layer 30 to the control gate 10.

On the other hand, in the example shown in FIG. 3B, an insulating film 33 is provided instead of the conductive layer 30. The energy bandgap of the insulating film 33 is smaller than the energy bandgap of the first insulating film 31. A portion of electrons injected from the channel body 20 into the insulating film 33 is captured by, for example, a trap in the insulating film 33. Thereby, data can be stored in the memory cell MC2. However, the amount of charge stored therein depends on a trap density, and is smaller than that of the memory cell MC1. Therefore, in the memory cell MC2, the shift amount of a threshold voltage corresponding to the storage of data becomes smaller.

An energy barrier ΔE₂ between the insulating film 33 and the fourth insulating film 40 is smaller than ΔE₁. For example, when the first layer 43 of the fourth insulating film 40 is formed of a silicon oxide film and the conductive layer 30 is formed of silicon, ΔE₁ is appropriately 3.5 eV, and ΔE₂ is appropriately 1.0 eV.

In the memory cell MC2, the electrons injected into the insulating film 33 are transferred into the fourth insulating film 40 in excess of the energy barrier ΔE₂ of 1.0 eV, and can flow into the control gate 10. That is, in the memory cell MC2, a gate leakage current becomes larger than in the memory cell MC1.

As shown in FIGS. 4A and 4B, during data erasure, a potential difference of, for example, −20 V is given between the control gate 10 and the channel body 20. Thereby, holes are injected from the channel body 20 through the first insulating film 31 into the conductive layer 30 and the insulating film 33. The holes injected into the conductive layer 30 and the insulating film 33 are recombined with the stored electrons. Thereby, the electrons stored in the conductive layer 30 and the insulating film 33 are annihilated, and thus data can be erased.

As shown in FIG. 5A, the electrons stored in the conductive layer 30 are held in a potential well surrounded by the energy barrier ΔE₁. Thereby, in the memory cell MC1, it is possible to stably hold charge in the conductive layer 30. In addition, the amount of charge capable of being held in the conductive layer 30 is larger than the amount of charge capable of being held by the memory cell MC2.

In the example shown in FIG. 5B, electrons captured by the trap in the insulating film 33 are held as stored charge. The depth E_{T} of the trap level of the insulating film 33 is, for example, 1 eV. When the insulating film 33 is formed of a silicon nitride film and the first insulating film 31 is formed of a silicon oxide film, an energy barrier ΔE₃ between the first insulating film 31 and the insulating film 33 is appropriately 1 eV. In a case where the electrons captured by the trap in the insulating film 33 are excited to a thermally valence band and can transfer through the insulating film 33, the electrons can be transferred out of the memory cell MC2 when the electrons exceed the energy barrier ΔE₃ of 1 eV.

On the other hand, when charge stored in the conductive layer 30 does not exceed the energy barrier ΔE₁ of at least 2.5 eV, the charge is not able to be transferred out of the memory cell MC1. That is, the memory cell MC1 is more excellent in the holding characteristics of charge than the memory cell MC2.

In this manner, the memory cell MC1 of the non-volatile memory device 1 according to the embodiment includes the conductive layer 30, and thus increases the amount of charge stored. In addition, the data holding characteristics of the memory cell MC1 are also improved. Further, the conductive layers 30 provided between each of the control gates 10 and the channel body 20 are separated from each other in the Z-direction with the third insulating film 35 and the fourth insulating film 37 interposed therebetween. Thereby, it is possible to restrict the transfer of the charge held in the conductive layer 30 in the Z-direction, and to improve the data holding characteristics.

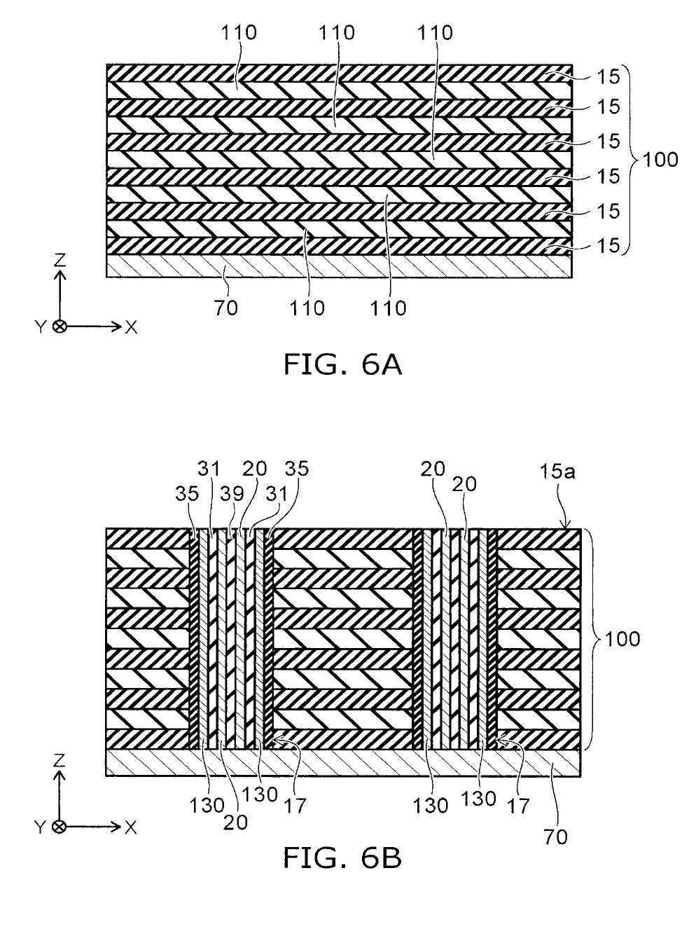

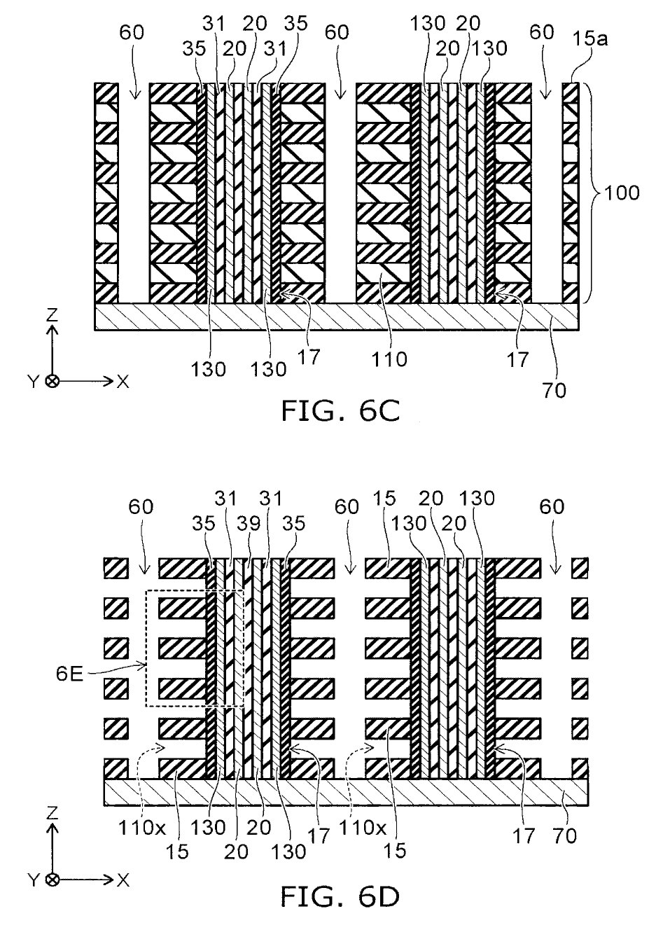

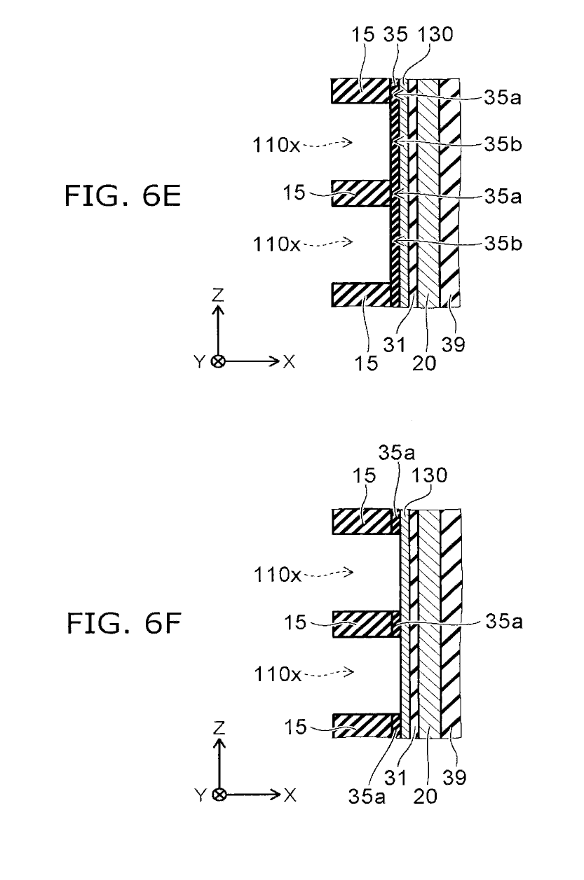

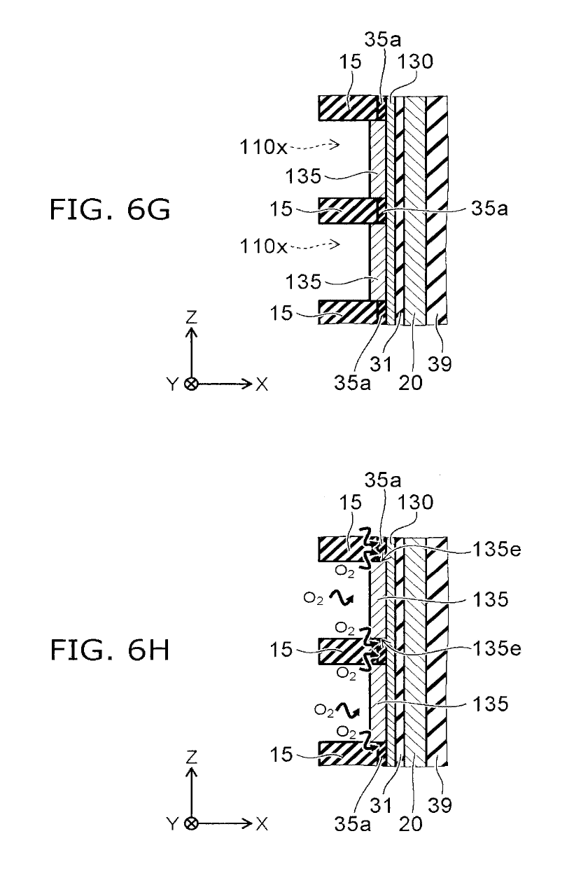

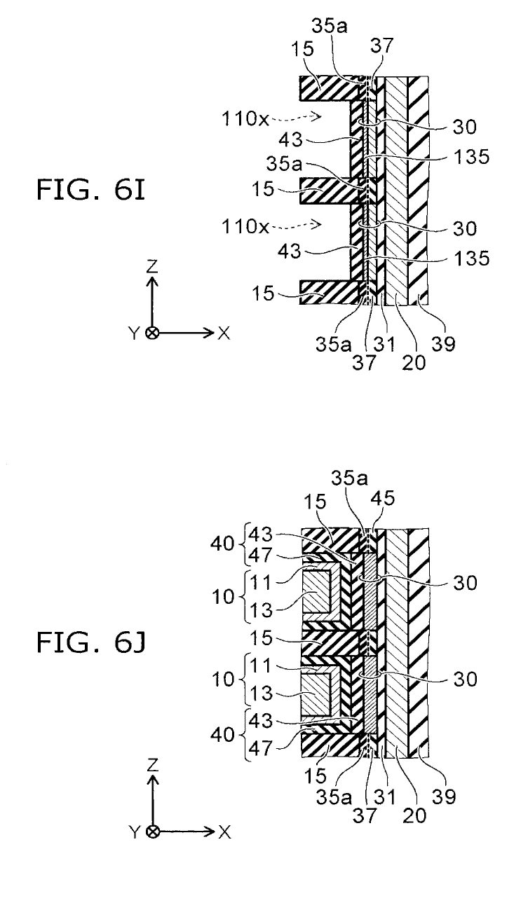

Next, a method for manufacturing the non-volatile memory device 1 according to the first embodiment will be described with reference to FIGS. 6A to 6J. FIGS. 6A to 6J are schematic cross-sectional views illustrating processes of manufacturing the non-volatile memory device 1.

As shown in FIG. 6A, for example, the interlayer insulating film 15 and a sacrifice film 110 are alternately stacked on the source interconnection 70 in the Z-direction. Thereby, a stacked body 100 including a plurality of interlayer insulating films 15 and a plurality of sacrifice films 110 is formed.

The interlayer insulating film 15 is, for example, a silicon oxide film. The sacrifice film 110 is, for example, a silicon nitride film. The interlayer insulating film 15 and the sacrifice film 110 can be continuously formed using, for example, a CVD (Chemical Vapor Deposition) method.

As shown in FIG. 6B, the memory hole 17 passing through the stacked body 100 in the Z-direction is formed. The channel body 20, the first insulating film 31, the first conductive film (hereinafter, conductive film 130), the third insulating film 35, and the core 39 are formed in the inside thereof.

For example, the memory hole 17 communicating from an interlayer insulating film 15a, which is an uppermost layer, of the plurality of interlayer insulating films 15 to the source interconnection 70 is formed. The memory hole 17 is formed by, for example, selectively etching the interlayer insulating film 15 and the sacrifice film 110 using RIE (Reactive Ion Etching).

The third insulating film 35, the conductive film 130 and the first insulating film 31 are formed in this order on the inner wall of the memory hole 17. The third insulating film 35 is, for example, a silicon oxide film. The conductive film 130 is, for example, a polycrystalline silicon (polysilicon) film. A silicon oxide film, for example, is used in the first insulating film 31. The first insulating film 31, the conductive film 130 and the third insulating film 35 are formed using, for example, a CVD method or an ALD (Atomic Layer Deposition) method.

The channel body 20 is formed on the first insulating film 31. The channel body 20 is, for example, a polysilicon film. The channel body 20 is formed using, for example, a CVD method or an ALD method. Subsequently, the core 39 is formed, and a space inside the memory hole 17 is buried. The core 39 has insulating properties, and is, for example, a silicon oxide film.

As shown in FIG. 6C, the slit 60 is formed. The slit 60 is a groove having a depth from the interlayer insulating film 15a to the source interconnection 70, and extends in the Y-direction. The slit 60 divides the stacked body 100 into a plurality of portions except the memory hole 17 of the stacked body 100. The slit 60 is formed by, for example, selectively etching the interlayer insulating film 15 and the sacrifice film 110 using RIE.

As shown in FIG. 6D, the sacrifice film 110 is selectively removed through the slit 60. For example, the interlayer insulating film 15 is a silicon oxide film, and the sacrifice film 110 is a silicon nitride film. In the inner wall of the memory hole 17, the third insulating film 35 that is in contact with the sacrifice film 110 is, for example, a silicon oxide film. The sacrifice film 110 can be selectively removed by, for example, wet etching using a hot phosphoric acid. The hot phosphoric acid is an etchant by which a silicon nitride film is etched and a silicon oxide film is not etched.

Hereinafter, processes of forming the control gate 10 and the conductive layer 30 will be described with reference to FIGS. 6E to 6J. FIGS. 6E to 6J are partially enlarged cross-sectional views showing a region 6E shown in FIG. 6D.

As shown in FIG. 6E, the interlayer insulating film 15 and the third insulating film 35 are exposed to a space 110x in which the sacrifice film 110 is removed. The third insulating film 35 includes a first portion 35a and a second portion 35b. The first portion 35a is located between the interlayer insulating film 15 and the first insulating film 31, and the second portion 35b is exposed to the space 110x.

As shown in FIG. 6F, the second portion 35b exposed to the space 110x is etched, and the conductive film 130 is exposed. For example, the interlayer insulating film 15 and the third insulating film 35 are etched using an etching condition in which a silicon oxide film is etched and a polysilicon film is not etched. Thereby, the conductive film 130 can be exposed to the inside of the space 110x. The thickness of the third insulating film 35 in a direction perpendicular to the Z-direction is formed to be smaller than the thickness of the interlayer insulating film 15 in the Z-direction. Therefore, it is possible to leave the interlayer insulating film 15 behind, and to remove the second portion 35b of the third insulating film 35.

As shown in FIG. 6G, the first conductive film (hereinafter, conductive film 135) is selectively formed on the conductive film 130 exposed to the space 110x. The conductive film 135 is, for example, a silicon film which is epitaxially grown. A source gas for forming the conductive film 135 is supplied through the slit 60 and the space 110x. When the conductive film 130 is, for example, a polysilicon film, silicon can be selectively grown thereon. That is, a silicon film is not formed on the interlayer insulating film 15. The conductive film 135 is, for example, single crystal silicon or polysilicon.

As shown in FIG. 6H, oxygen O₂ is supplied, and the conductive film 135 is oxidized. Oxygen O₂ is supplied through the slit 60 and the space 110x. The conductive film 135 is, for example, thermally oxidized. In addition, oxygen radicals obtained by ionizing oxygen atoms using plasma or the like may be supplied, and the conductive film 135 may be oxidized.

A silicon oxide film has a property of allowing the passage of oxygen therethrough. Therefore, when the interlayer insulating film 15 and the third insulating film 35 are silicon oxide films, oxygen passes through the interlayer insulating film 15 and the first portion 35a of the third insulating film 35, and reaches the conductive film 130. Thereby, it is possible to oxidize a portion of the conductive film 130 that is in contact with the first portion 35a, simultaneously with the conductive film 135.

FIG. 6I shows a structure after the conductive films 130 and 135 are oxidized. A portion in which the conductive film 135 is oxidized serves as the first layer 43, and the remaining portion of the conductive film 130 is included in the conductive layer 30. The first layer 43 is, for example, a silicon oxide film.

The portion of the conductive film 130 oxidized between the first portion 35a of the third insulating film 35 and the first insulating film 31 serves as the fourth insulating film 37. The fourth insulating film 37 is, for example, a silicon oxide film.

A plurality of conductive layers 30 are formed by the above-mentioned oxidation. The conductive layer 30 includes a portion in which the conductive films 130 and 135 are not oxidized. The plurality of conductive layers 30 are formed so as to be separated from each other in the Z-direction through the first portion 35a of the third insulating film 35 and the fourth insulating film 37.

In this example, an example is illustrated in which the conductive film 130 which is a silicon layer and the conductive film 135 which is a polysilicon film are oxidized, but the embodiment is not limited thereto. For example, the conductive films 130 and 135 may be nitrided by supplying nitrogen radicals instead of oxygen.

As shown in FIG. 6J, in the inside of the space 110x, the second layer 47 is formed on the first layer 43 obtained by oxidizing a portion of the conductive film 130. The second layer 47 is also formed on the interlayer insulating film 15. Further, the control gate 10 that buries the inside of the space 110x is formed.

The control gate 10 includes, for example, the first electrode layer 11 and the second electrode layer 13. The first electrode layer 11 is formed on the second layer 47, and the second electrode layer 13 is formed on the first electrode layer 11. The second electrode layer 13 buries the inside of the space 110x. The first electrode layer 11 is, for example, a titanium nitride (TiN). The first electrode layer 11 functions as a barrier metal for suppressing the transfer of metal atoms from the control gate 10 to the memory cell MC1. The second electrode layer 13 is, for example, tungsten (W).

The fourth insulating film 40 includes the first layer 43 and the second layer 47. The second layer 47 is, for example, an aluminum oxide (Al₂O₃). The dielectric constant of the second layer 47 is larger than, for example, the dielectric constant of the first layer 43. Thereby, it is possible to reduce the electric field of the first layer 43, and to reduce a gate leakage current flowing from the conductive layer 30 to the control gate 10.

In this example, after the processes shown in FIGS. 6A to 6J, the insulating film 61 that buries the inside of the slit 60 is formed. Further, the selection transistor 50 and the bit line 80 are formed, and the non-volatile memory device 1 is completed. The embodiment is not limited to this example. For example, in the process of stacking the interlayer insulating film 15 and the sacrifice film 110 shown in FIG. 6A, a portion constituting the selection transistor 50 may be further stacked.

In the above-mentioned manufacturing process, oxygen O₂ is supplied through the space 110x in which the sacrifice film 110 is removed. Therefore, at an end 135e of the conductive film 135 in the Z-direction or a direction opposite thereto, an oxidation rate in the corner on the space 110x side increases. For this reason, the conductive layer 30 formed by oxidation has a shape in which the thickness d_{CS} in a direction perpendicular to the Z-direction becomes smaller as the thickness approaches the end 30e. In addition, the conductive layer 30 is formed so as to have a convex shape in the direction of the space 110x.

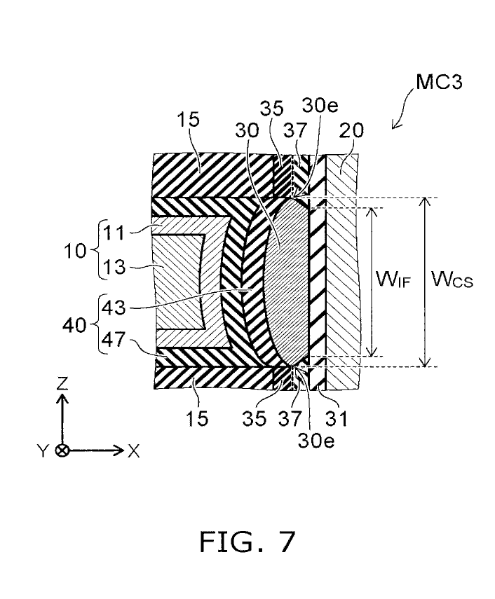

FIG. 7 is a schematic diagram illustrating a structure of a memory cell MC3 according to a variation of the first embodiment. For example, it is possible to optimize the structure of the memory cell by controlling the thickness of the conductive layer 130 in a direction perpendicular to the Z-direction, and the time of oxidation.

As shown in FIG. 7, the maximum width W_{CS} of the conductive layer 30 in the Z-direction can be formed to be larger than the length W_{IF} of an interface between the conductive layer 30 and the first insulating film 31. The memory cell MC3 is formed, for example, by making the oxidation time of the conductive films 130 and 135 longer than in the memory cell MC1 shown in FIG. 2B. In this example, the maximum width W_{CS} of the conductive layer 30 is also larger than the width W_{EL} of the control gate 10 in the Z-direction.

As stated above, the non-volatile memory device 1 according to the embodiment includes the conductive layers 30 which are separated from each other in the Z-direction. The conductive layer 30 becomes smaller in a thickness d_{CS} in a direction perpendicular to the Z-direction as the conductive layer is closer to the end 30e in the Z-direction or a direction opposite thereto, and has a convex shape in a direction from the channel body 20 toward the control gate 10. Further, the width W_{EL} of the control gate 10 in the Z-direction is provided to be smaller than the width W_{CS} of the conductive layer 30 in the Z-direction. Thereby, in the memory cells MC1 and MC3 including the conductive layer 30, it is possible to increase the amount of charge stored, and to improve the data holding characteristics. In addition, the shape of the conductive layer 30 increases coupling between the control gate 10 and the memory cells MC1 and MC3, and increases the amount of charge capable of being stored. Thereby, it is possible to improve the reliability of the non-volatile memory device 1.

### Second Embodiment

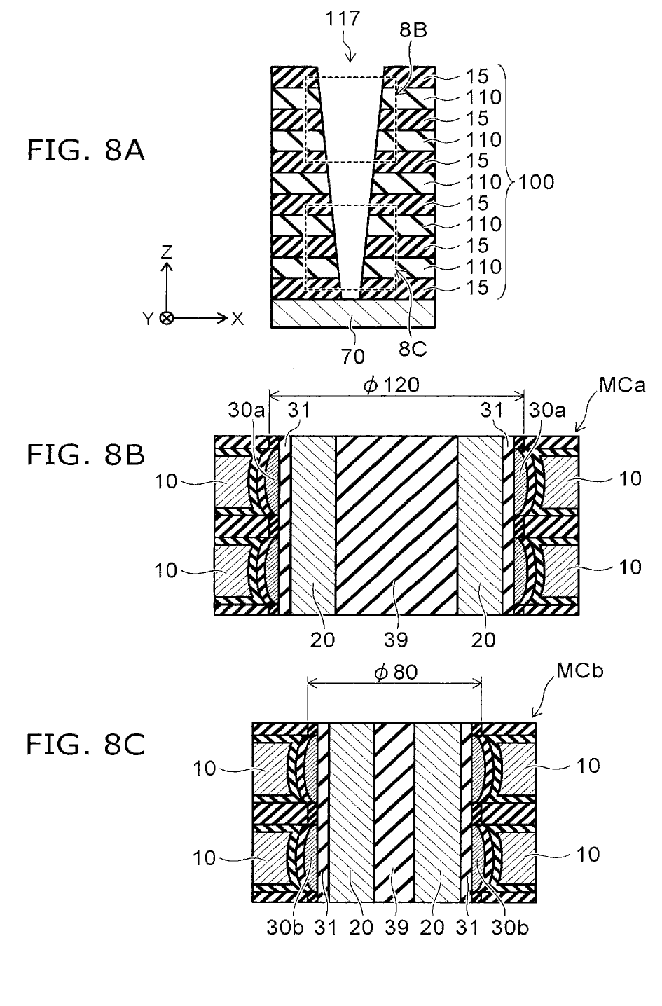

FIGS. 8A to 8C are schematic views illustrating a non-volatile memory device 2 according to a second embodiment. FIG. 8A is a schematic cross-sectional view illustrating a shape of a memory hole 117 of the non-volatile memory device 2. FIG. 8B is a partial cross-sectional view illustrating a first memory cell (hereinafter, memory cell MCa) provided in a region 8B shown in FIG. 8A. FIG. 8C is a partial cross-sectional view illustrating a second memory cell (hereinafter, memory cell MCb) provided in a region 8C shown in FIG. 8A.

As shown in FIG. 8A, the memory hole 117 is configured such that its diameter in a direction perpendicular to the Z-direction is smaller at the source interconnection 70 side. For example, when the stacked body 100 is etched using RIE to form the memory hole 117, there is a tendency for the diameter to decrease in a depth direction.

As shown in FIG. 8B, the memory cell MCa includes a first conductive layer (hereinafter, conductive layer 30a). In addition, as shown in FIG. 8C, the memory cell MCb includes a second conductive layer (hereinafter, conductive layer 30b). The diameter of the conductive layer 30a in a direction perpendicular to the Z-direction is larger than the diameter of the conductive layer 30b in a direction perpendicular to the Z-direction.

For example, even when the same control voltage is applied between the control gate 10 and the channel body 20, in the memory cell MCb provided in the region 8C, the electric field of the tunnel insulating film (that is, first insulating film 31) becomes higher than the electric field of the tunnel insulating film of the memory cell MCa provided in the region 8B, due to a curvature effect. As a result, for example, a minimum voltage required for writing data in the memory cell MCa becomes higher than a minimum voltage required for writing data in the memory cell MCb. For example, when the writing voltage of the non-volatile memory device 2 is set to a level at which data is written in the memory cell MCa, an excessive voltage is applied to the memory cell MCb.

On the other hand, in the embodiment, the coupling ratio of the memory cell MCb is made to be smaller than the coupling ratio of the memory cell MCa. Thereby, it is possible to reduce the electric field of the tunnel insulating film of the memory cell MCb, and to make the writing voltage uniform.

Specifically, in the process of forming the conductive film 130 shown in FIG. 6G, for example, the pressure of epitaxial growth is made to be higher, and thus the conductive film 130 located above the memory hole 17 is formed to be thicker than the conductive film 130 located below the memory hole 17. In the oxidation process shown in FIG. 6H, as the conductive film 130 is thicker, the oxidation of the end progresses more rapidly due to the shape effect. For this reason, at the upper portion side of the memory hole 117, the conductive layer 30 has a shape in which the area of a surface facing the control gate 10 is larger. As a result, the coupling ratio of the memory cell MCa can be made to be higher than the coupling ratio of the memory cell MCb.

In this manner, in the embodiment, the coupling ratio of the memory cell MCa provided at the upper portion of the memory hole 117 is made to be higher than the coupling ratio of the memory cell MCb provided at the lower portion thereof, and thus it is possible to improve the non-uniformity of a writing voltage (or erasing voltage), and to improve the reliability of the non-volatile memory device 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a plurality of electrodes arranged side by side in a first direction;
at least one semiconductor layer extending into the electrodes in the first direction;
conductive layers provided between each of the electrodes and the semiconductor layer, the conductive layers being separated from each other in the first direction;
a first insulating film extending between the conductive layer and the semiconductor layer in the first direction along the semiconductor layer; and
a second insulating film provided between each of the electrodes and the conductive layers,
the conductive layers becoming smaller in a thickness in a direction perpendicular to the first direction as the conductive layers are closer to an end of each of the conductive layers in the first direction or a direction opposite to the first direction, and having a convex shape in a direction from the semiconductor layer toward each of the electrodes.

2. The device according to claim 1, wherein
the second insulating film includes a first layer and a second layer,
the first layer is provided between the conductive layers and the second layer, and
the second layer has a dielectric constant higher than a dielectric constant of the first layer.

3. The device according to claim 2, further comprising a plurality of interlayer insulating films respectively provided between the electrodes,
the second layer extending between each of the electrodes and the interlayer insulating films adjacent to each of the electrodes.

4. The device according to claim 2, wherein the first layer includes an oxide of elements constituting the conductive layer.

5. The device according to claim 4, wherein
the conductive layer is a silicon layer,
the first layer includes a silicon oxide, and
the second layer includes an aluminum oxide.

6. The device according to claim 1, further comprising:
a plurality of interlayer insulating films respectively provided between the electrodes; and
a third insulating film provided between the interlayer insulating films and the first insulating film.

7. The device according to claim 6, further comprising a fourth insulating film provided between the first insulating film and the third insulating film, the fourth insulating film including an oxide of elements constituting the conductive layer.

8. The device according to claim 7, wherein
the conductive layers are a silicon layer, and
the fourth insulating film is a silicon oxide film.

9. The device according to claim 1, wherein a width of the conductive layers in the first direction is larger than a width of the electrodes in the first direction.

10. The device according to claim 9, wherein
the conductive layers is in contact with the first insulating film, and
the width of the conductive layers in the first direction is larger than a length of an interface in the first direction, wherein the interface is in contact with the first insulating film.

11. The device according to claim 1, further comprising:
a first memory cell including a first conductive layer provided between an end electrode of the electrodes and the semiconductor layer; and
a second memory cell including a second conductive layer provided between another end electrode of the electrodes and the semiconductor layer,
a diameter of a cross-section of the first conductive layer perpendicular to the first direction being larger than a diameter of a cross-section of the second conductive layer perpendicular to the first direction, and
a coupling ratio of the first memory cell being larger than a coupling ratio of the second memory cell.

12. A method for manufacturing a non-volatile memory device, comprising:
alternately stacking interlayer insulating films and sacrifice films in a first direction, and forming a stacked body including a plurality of the interlayer insulating films and a plurality of the sacrifice films;
forming a memory hole passing through the stacked body in the first direction;
forming a semiconductor layer, a first insulating film, a first conductive film and a third insulating film within the memory hole, and stacking in order of the third insulating film, the first conductive film, the first insulating film and the semiconductor layer on an inner wall of the memory hole;
forming a slit dividing the stacked body excluding the memory hole into a plurality of portions;
selectively removing the sacrifice films through the slit;
leaving a first portion of the third insulating film located between the interlayer insulating films and the first insulating film, removing a second portion of the third insulating film exposed after removing the sacrifice films, and exposing the first conductive film;
selectively forming a second conductive film on the first conductive film;
oxidizing at least a portion of the second conductive film and the first conductive film in contact with the first portion, and forming a plurality of conductive layers separated from each other in the first direction; and
depositing an electrode layer in a space where the sacrifice films are selectively removed with a second insulating film interposed.

13. The method according to claim 12, wherein
the first conductive film is a silicon film, and
the forming of the second conductive layer includes a process of growing a silicon crystal on the first conductive film.

14. The method according to claim 12, wherein a portion of the second conductive film and a portion of the first conductive film in contact with the first portion are thermally oxidized.

15. The method according to claim 12, wherein the second insulating film includes a first layer where the second conductive film is oxidized and a second layer having a dielectric constant higher than a dielectric constant of the first layer.
